(19) United States
(12) Patent Application Publication
(10) Pub. No.: US 2016/0013126 A1
(43) Pub. Date: Jan. 14, 2016

(54) PACKAGE SUBSTRATE AND METHOD OF FABRICATING SEMICONDUCTOR PACKAGE

(71) Applicant: SAMSUNG ELECTRONICS CO., LTD., Suwon-si (KR)

(72) Inventors: JinGyu KIM, Suwon-si (KR); Hyun LEE, Busan (KR)

(73) Assignee: SAMSUNG ELECTRONICS CO., LTD., Suwon-si (KR)

(21) Appl. No.: 14/746,981

(22) Filed: Jun. 23, 2015

(30) Foreign Application Priority Data
Jul. 11, 2014 (KR) 10-2014-0087673

(51) Int. Cl. H01L 23/498; H01L 23/00; H01L 23/31

(52) U.S. Cl. CPC H01L 23/49838; H01L 23/3107; H01L 24/05; H01L 24/97; H01L 2924/15151

(57) ABSTRACT

Provided are a package substrate and a method of fabricating a semiconductor package. The package substrate includes: a base substrate having a plurality of packaging unit regions arranged along rows and columns on one surface thereof; and a sink portion penetrating at least a portion of the base substrate from the one surface, in which the packaging unit regions may be disposed adjacent to a first side of the one surface and the sink portion may be disposed adjacent to a second side of the one surface.

### CROSS-REFERENCE TO THE RELATED APPLICATIONS

This application claims priority from Korean Patent Application No. 10-2014-0087673, filed on Jul. 11, 2014, the disclosure of which is incorporated herein in its entirety by reference.

### BACKGROUND

Apparatuses consistent with exemplary embodiments of the inventive concept relate to a semiconductor, and more particularly, to a package substrate and a fabrication of a semiconductor package using the same.

According to high density and high integration of a semiconductor integrated circuit used in electronic devices, it is a recent trend in the art to allow electrode terminals of a semiconductor chip to have more pins and narrower pitch. A printed circuit board (PCB) is widely used to reduce a size of a semiconductor package. Also, a flip-chip bonding mounting using bumps is widely used to reduce a wire delay in mounting a semiconductor chip on a PCB. A method of molding a space between a semiconductor chip and a circuit board not using an additional underfill resin but using a molding layer for a semiconductor package has been studied. At this time, when flowability of a molding compound is not controlled, a void is formed and remains inside a molding layer, thus causing a degradation of a molding process quality and a product defect.

### SUMMARY

Exemplary embodiments of the inventive concept provide a package substrate for fabricating a reliable semiconductor package.

The embodiments also provide a method of fabricating a reliable semiconductor package.

According to an exemplary embodiment, there is provided a package substrate which may include: a base substrate having a plurality of packaging unit regions arranged along rows and columns on one surface thereof; and a sink portion oriented toward the other surface of the base substrate opposed to the one surface from the one surface, in which the packaging unit regions are disposed adjacent to a first side of the one surface, the sink portion is disposed adjacent to a second side of the one surface, and the second side is opposed to the first side and parallel to a direction of the rows.

Here, a distance from the packaging unit regions of a first row to the first side of the one surface may be shorter than a distance from the packaging unit regions of a last row to the second side of the one surface.

A total number of the columns may be greater than a total number of the rows.

The sink portion may penetrate the base substrate and connects the one surface and the other surface.

Otherwise, the sink portion may be recessed from the one surface.

The sink portion may include a plurality of sink portions and the sink portions are offset arranged in a direction of the rows with respect to the packaging unit regions of a last row.

Each of the packaging unit regions may include: a chip region on which a semiconductor chip is mounted; and an edge region surrounding the chip region.

The sink portion may be disposed spaced apart from the packaging unit regions.

According to another exemplary embodiment, there is provided a method of fabricating a semiconductor package which may include: providing a package substrate including a sink portion; mounting semiconductor chips on one surface of the package substrate; and forming a molding layer covering the semiconductor chips on the one surface, in which the molding layer is formed sequentially from the semiconductor chips adjacent to a first side of the package substrate, the sink portion is oriented toward the other surface of the package substrate opposed to the one surface, from the one surface of the package substrate, the sink portion is provided between the semiconductor chips and a second side of the package substrate, and the second side may be opposed to the first side.

The forming of the molding layer may include filling the sink portion with a molding compound.

The sink portion may be provided in plurality and the plurality of sink portions may be arranged in parallel to the second side.

The mounting of the semiconductor chips may include disposing the semiconductor chips along rows and columns on the one surface of the package substrate in which the rows may be parallel to the first side.

Connection portions may be provided between the package substrate and the semiconductor chips, and the molding layer may fill may further extend between the package substrate and the molding layer to fill a space between the connection portions.

According to still another exemplary embodiment, there is provided a package substrate which may include: a base substrate having a plurality of packaging unit regions arranged along rows and columns on one surface thereof; and a sink portion oriented toward the other surface of the base substrate opposed to the one surface from the one surface, in which a shortest distance from the packaging unit regions to a first side of the one surface is shorter than a shortest distance from the packaging unit regions to a second side of the one surface, the sink portion is provided between the packaging unit regions of a last row and the second side, and the second side is opposed to the first side.

The rows may be parallel to a direction of a major axis of the one surface and the columns are parallel to a direction of a minor axis of the one surface.

The sink portion may include a plurality of the sink portions and the plurality of sink portions may be arranged parallel to a direction of the rows.

A center point of each of the packaging unit regions of the last row may be offset in the direction of the rows from a center point of each of the sink portions.

A total number of columns may be greater than a total number of rows.

A major axis of the sink portion may be parallel to a direction of the rows.

Each of the packaging unit regions may include conductive pads.

According to still another exemplary embodiment, there is provided a semiconductor package which may include: a base substrate comprising a plurality of packaging unit regions disposed on one side of an upper surface thereof; a plurality of semiconductor chips disposed above the plurality of packaging units; a sink portion oriented from the upper surface of the base substrate, and disposed on the other side of the base substrate separate from the one side of the base substrate; and a molding layer covering the semiconductor chips and the upper surface of the base substrate, wherein the one side of the base substrate is a side from which a molding material constituting the molding layer is flown to cover the semiconductor chips and the upper surface of the base substrate.

The sink portion may penetrate the base substrate, and connects the upper surface and a bottom surface of the base substrate, so that the molding material fills in the sink portion. The semiconductor package may further include a mold which comprises a lower frame disposed below the bottom surface of the base substrate configured to prevent flow of the molding material beyond the base substrate. A portion of the lower frame contacting the molding material may be a polymer, and the molding material may be substantially similar to a material constituting the upper surface of the base substrate.

### BRIEF DESCRIPTION OF THE DRAWINGS

The accompanying drawings are included to provide a further understanding of the exemplary embodiments, and are incorporated in and constitute a part of this specification. In the drawings:

FIGS. 1A to 4A are plane views describing a method for fabricating a semiconductor package, according to an exemplary embodiment;

FIGS. 1B to 1D are cross sectional views taken along line □-□ of FIG. 1A, respectively, according to an exemplary embodiment;

FIG. 2B is a cross sectional view taken along line □-□ of FIG. 2A, according to an exemplary embodiment;

FIGS. 3B to 3C are cross sectional views taken along line □-□ and □′-□′ of FIG. 3A, respectively, according to an exemplary embodiment;

FIG. 4B is a cross sectional view taken along line □-□ of FIG. 4A, according to an exemplary embodiment;

FIG. 5A is a plane view showing a package substrate according to another exemplary embodiment;

FIG. 5B is a cross sectional view showing a semiconductor package fabricated by using the package substrate of FIG. 5A, according to an exemplary embodiment;

FIG. 6A is a plane view showing a mold and a molding layer formation using the mold, according to another exemplary embodiment;

FIGS. 6B to 6D are cross sectional views showing a mold and a forming of a molding layer using the mold, according to another exemplary embodiment, taken along line □-□ of FIG. 6A;

FIGS. 7A to 7D are plane views showing a package substrate, according to another exemplary embodiment;

FIG. 8 is a block diagram showing a memory card provided with a semiconductor package, according to an exemplary embodiment; and

FIG. 9 is a block diagram showing an information processing system applying a semiconductor package, according to an exemplary embodiment.

### DETAILED DESCRIPTION OF THE EXEMPLARY EMBODIMENTS

Exemplary embodiments of the inventive concept will be described below in more detail with reference to the accompanying drawings. The inventive concept may, however, be embodied in different forms and should not be construed as limited to the embodiments set forth herein. Rather, these embodiments are provided such that this disclosure will be thorough and complete, and will fully convey the scope of the inventive concept to those skilled in the art.

As used herein, the term ‘and/or’ includes any and all combinations of one or more of the associated listed items. Also, it will be understood that when an element is referred to as being ‘connected/coupled to’ another element, it can be directly connected or coupled to another element, or intervening elements may be present. It will also be understood that when a layer (or film) is referred to as being ‘on’ another layer or substrate, it can be directly on the other layer or substrate, or intervening layers may also be present. In the following description, the technical terms are used only for explaining a specific exemplary embodiment while not limiting the inventive concept. The terms of a singular form may include plural forms unless referred to the contrary. The meaning of “include,” “comprise,” “including,” or “comprising,” specifies a property, a region, a fixed number, a step, a process, an element and/or a component but does not exclude other properties, regions, fixed numbers, steps, processes, elements and/or components.

Also, though terms like a first, a second, and a third are used to describe various regions and layers in various exemplary embodiments, the regions and the layers are not limited to these terms. These terms are used only to discriminate one region or layer (or film) from another region or layer (or film). These terms are used only to discriminate one region or layer from another region or layer. Therefore, a layer (or film) referred to as a first layer (or film) in one embodiment can be referred to as a second layer (or film) in another embodiment. An embodiment described and exemplified herein may include a complementary embodiment thereof. Throughout this specification, like reference numerals are used for referring to the same or similar elements in the description and drawings.

Additionally, the embodiment in the detailed description will be described with sectional views and/or plane views as ideal exemplary views of the present embodiment. In the drawings, the size or dimension of elements are exaggerated for clarity of illustration. Accordingly, shapes of the exemplary views may be modified according to fabricating techniques and/or allowable errors. Therefore, the embodiments are not limited to the specific shape illustrated in the exemplary views, but may include other shapes that may be created according to fabricating processes. For example, an etched region illustrated as a rectangle may have rounded or curved features. Areas exemplified in the drawings have general properties, and are used to illustrate a specific shape of a semiconductor package region. Thus, this should not be construed as limited to the scope of the embodiment.

Hereinafter, a method of fabricating a package substrate and a semiconductor package fabricated therewith are described with reference to the accompanying drawings.

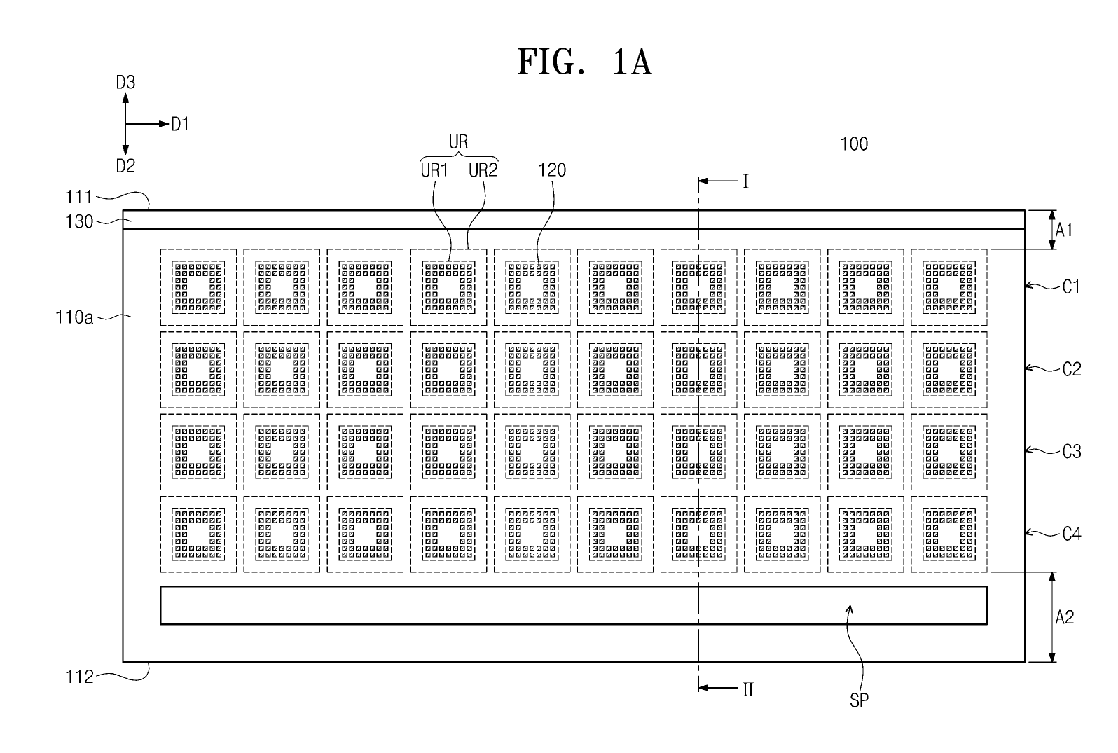

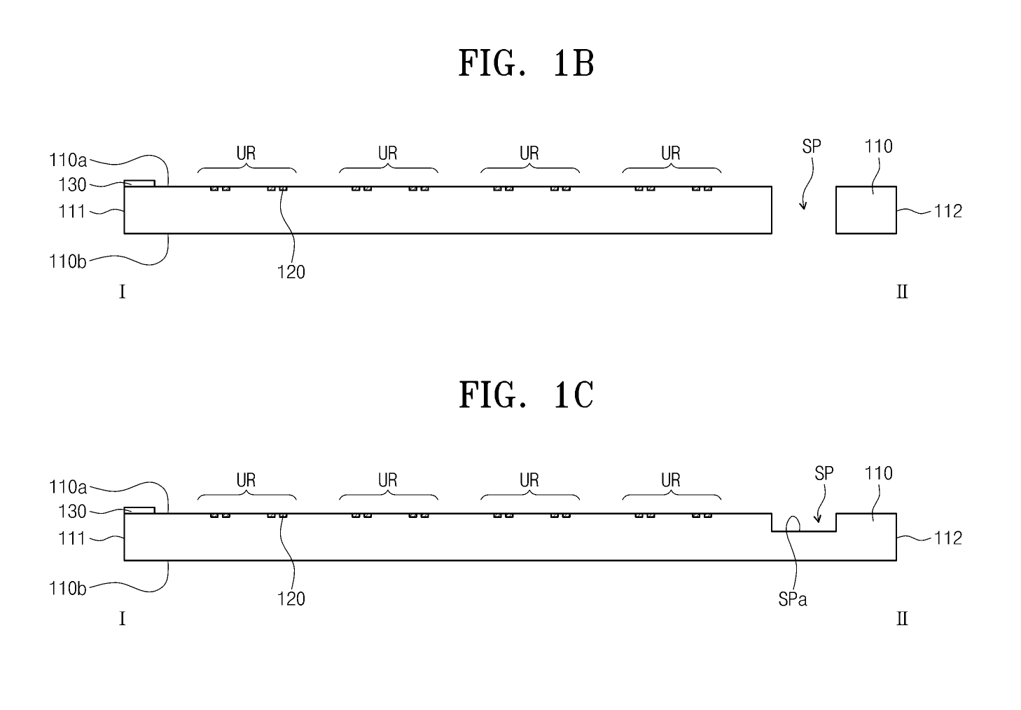

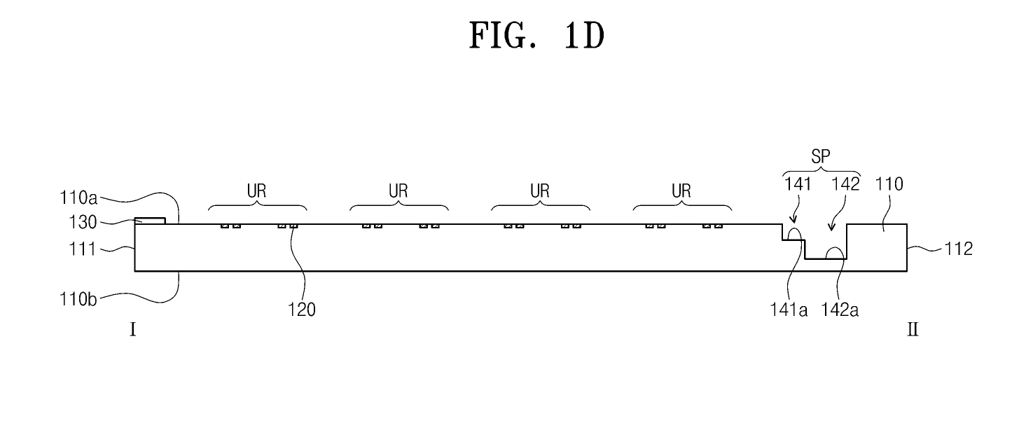

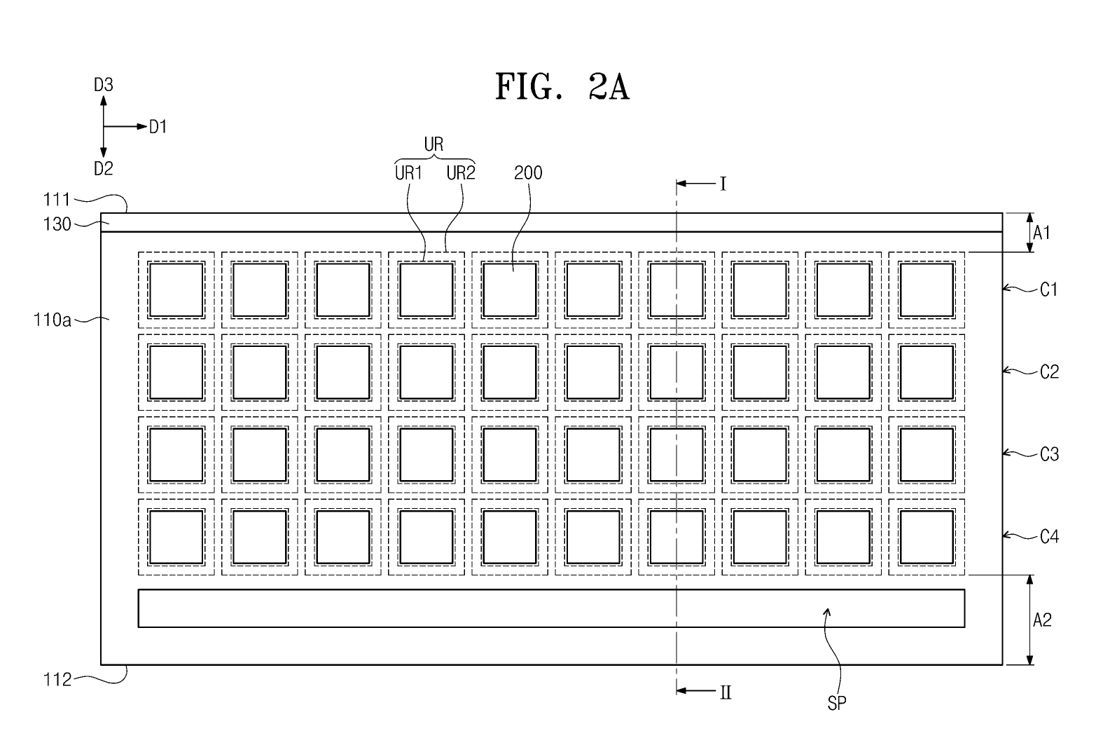

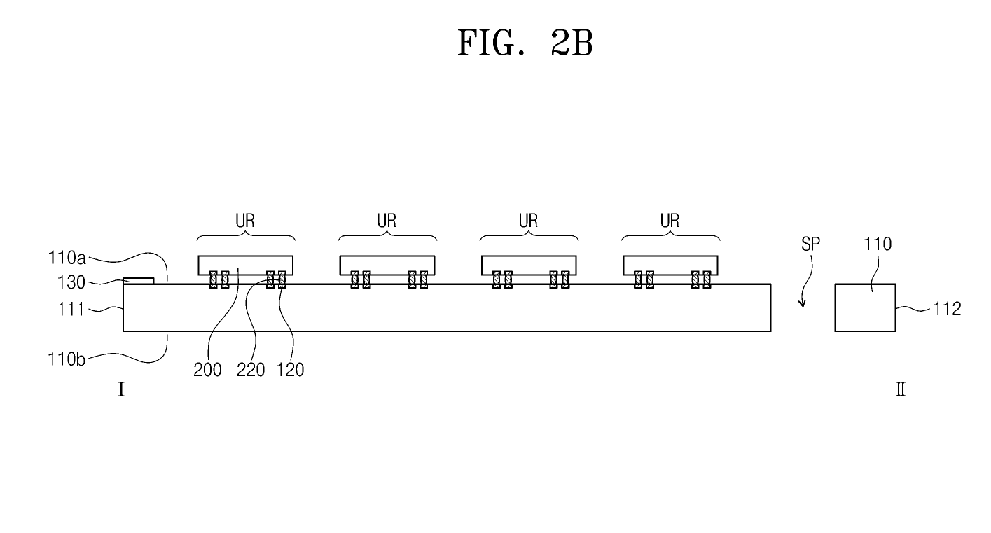

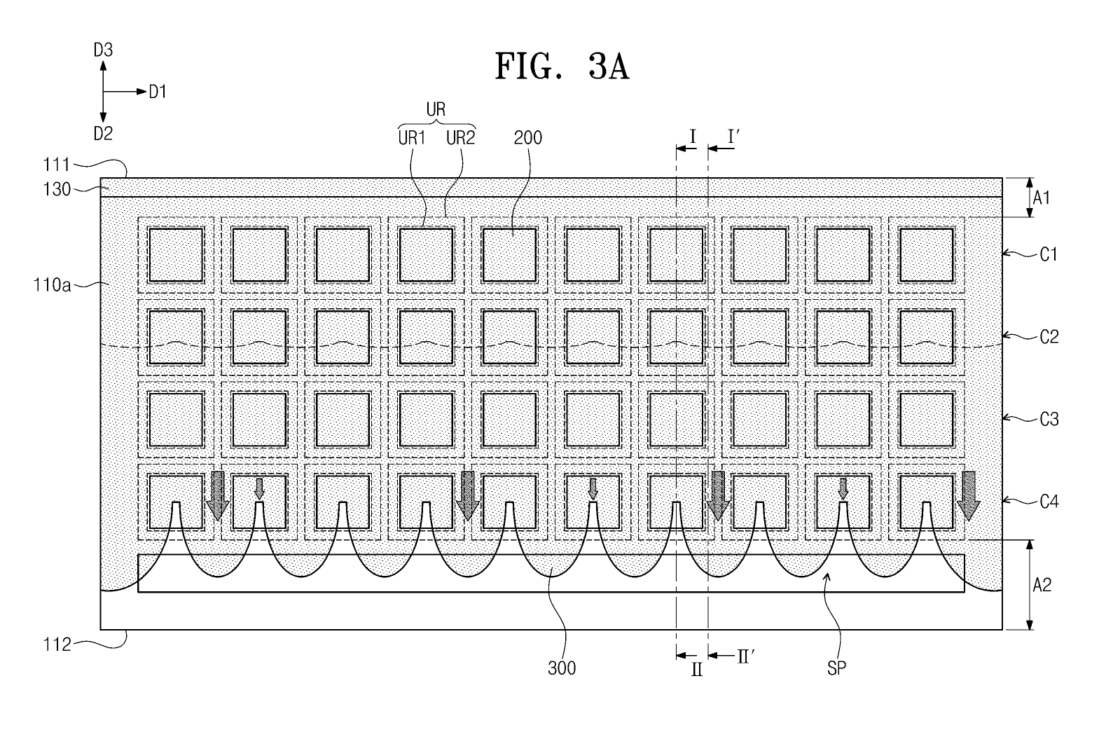

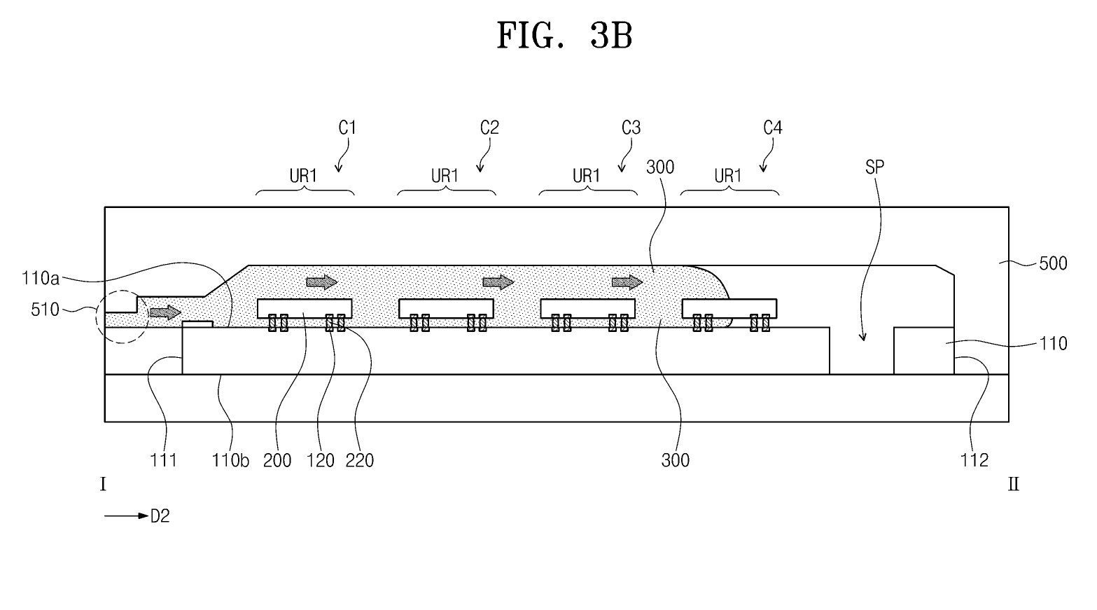

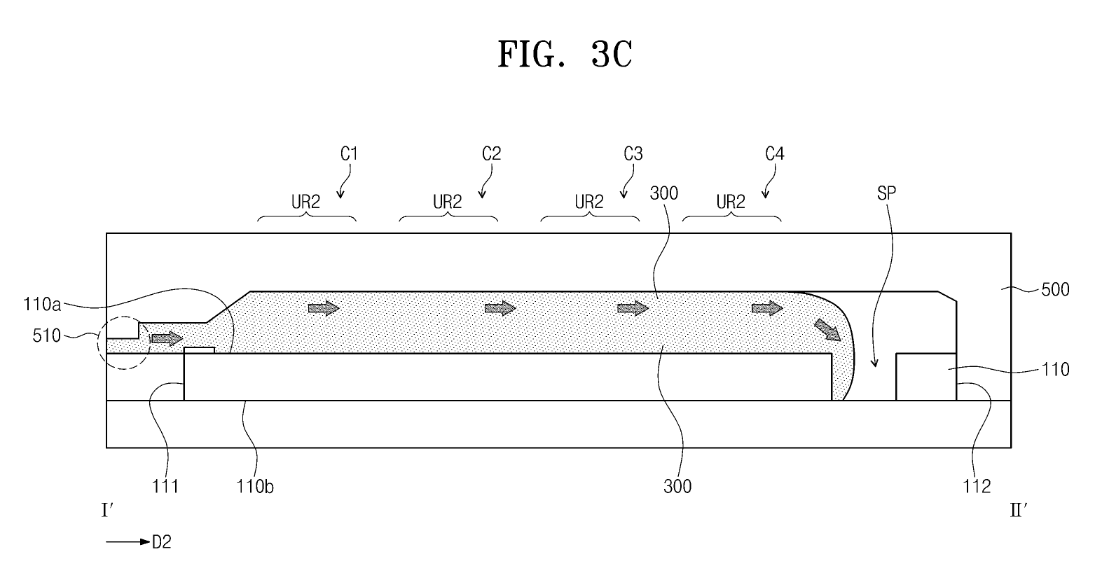

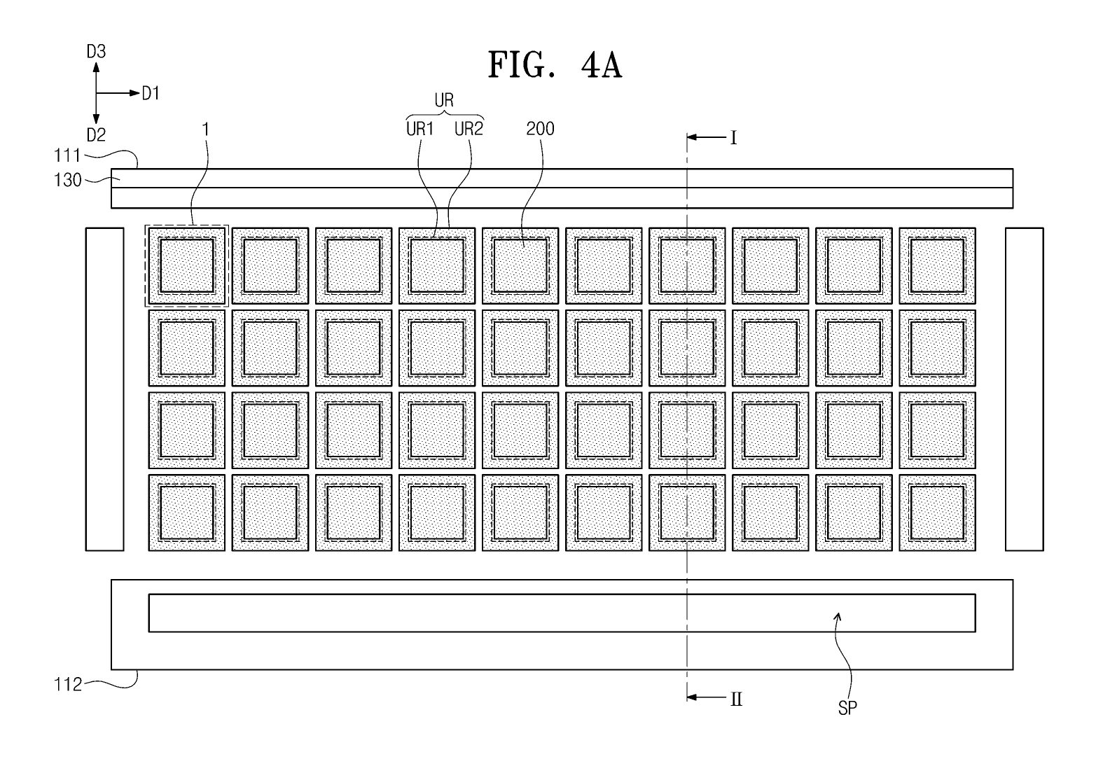

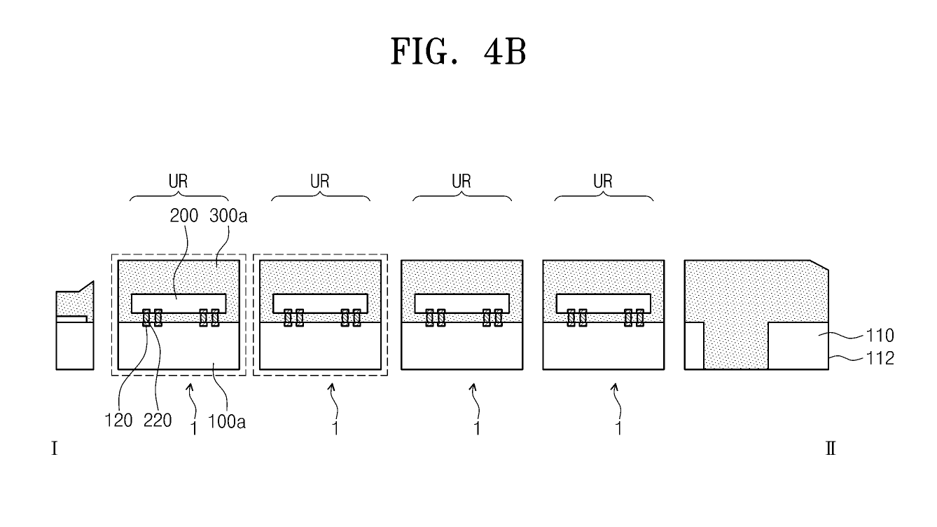

FIGS. 1A to 4A are plane views illustrating a method of fabricating a semiconductor package according to an exemplary embodiment. FIGS. 1B to 1D are cross-sectional views taken along line □-□ of FIG. 1A, respectively, and illustrate package substrates according to an exemplary embodiment. FIG. 2B is a cross-sectional view taken along line □-□ of FIG. 2A. FIGS. 3B and 3C are cross-sectional views taken along line □-□ and □′-□′ of FIG. 3A, respectively. FIG. 4B is a cross-sectional view taken along line □-□ of FIG. 4A.

Referring to FIG. 1A, a package substrate 100 may include a base substrate 110 and a sink portion SP. The package substrate 100 may be a printed circuit board PCB including a circuit pattern. One surface 110a of the base substrate 110 may include a major axis and a minor axis which are perpendicular to each other. The major axis may be parallel to a first direction D1 and the minor axis may be parallel to a second direction. One surface 110a of the base substrate 100 may be covered with a polymer, such as a solder resist material.

Unit regions UR may be provided on the one surface 110a of the base substrate 110. In a planar view, the unit regions UR may be arranged along a plurality of rows C1 to C4. At this time, each of the rows C1 to C4 may be parallel to the first direction D1. The first row C1 may be adjacent to a first side 111 and the last row C4 may be adjacent to a second side 112. The first side 111 and the second side 112 may be parallel to the first direction D1, and the second side 112 may be opposed to the first side 111. The unit regions UR may be arranged along a plurality of columns. The columns may be parallel to the second direction D2 and perpendicular to the rows C1 to C4. A total number of the columns may be greater than a total number of the rows C1 to C4.

The unit regions UR may be arranged at regular intervals. For example, distances between center points of the unit regions UR constituting the first row C1 may be equal to one another. Distances between the center points of the unit regions UR constituting the first row C1 may be equal to distances between the center points of the unit regions UR constituting the second row C1. Distances between the center points of the unit regions UR constituting each of the rows may be equal to one another. Distances between the center points of the unit regions UR constituting different rows may be equal to one another.

When the unit regions UR are shift-arranged in a third direction D3, the unit regions UR may be further adjacent to the first side 111. The third direction D3 is an opposite direction to the second direction D2. For example, a distance A1 from unit regions UR of the first row C1 to the first side 111 may be shorter than a distance A2 from unit regions UR of the last row C4 to the second side 112.

The unit regions UR may have chip regions UR1 and edge regions UR2 surrounding the chip regions UR1. The chip regions UR1 may be regions on which semiconductor chips (200 of FIGS. 2A and 2B) are disposed. The chip regions UR1 may have a cross sectional area of about 50% or more of the unit regions UR. In a planar view, the chip regions UR1 may be arranged corresponding to the unit regions UR. For example, the chip regions UR1 may be arranged along the rows C1 to C4 and the columns. The chip areas UR1 may be shift-arranged in the third direction D3 to be adjacent to the first side 111.

Each of the unit regions UR may have a plurality of pads 120. The pads 120 may include a conductive material, for example, metal. The pads 120 may have various arrays.

In a planar view, the sink portion SP may be disposed adjacent to the second side 112 on the one surface 110a. For example, the sink portion SP may be provided between the unit regions UR of the last row C4 and the second side 112. The sink portion SP may extend in a direction parallel to the rows C1 to C4, and may be parallel to the first direction D1. The sink portion SP may be formed at a position corresponding to the columns of the respective unit regions. For example, the sink portion SP may be provided on the same lines with the columns of the unit regions UR. The plane of the sink portion SP may have a rectangular shape, but is not limited thereto.

The sink portion SP may be formed by etching at least a portion of the base substrate 110. The sink portion SP may be provided by penetrating at least a portion of the base substrate 110 on one surface 110a. Hereinafter, a cross-section of the sink portion SP according to exemplary embodiments is described in more detail.

Referring to FIG. 1B, the sink portion SP may penetrate the base substrate 110 to connect the one surface 110a of the base substrate 110 and the other surface 110b of the base substrate. At this time, the other surface 110b may be opposed to the one surface 110a.

Referring to FIG. 1C, unlike FIG. 1B, the sink portion SP may be recessed from the one surface 110a of the base substrate 110 by etching a portion of the base substrate 110. For example, while a bottom surface SPa of the sink portion SP has a lower level than the one surface 110a of the base substrate 110, the bottom surface SPa of the sink portion SP may be spaced apart from the other surface 110b of the base substrate 110.

Referring to FIG. 1D, unlike FIG. 1B, the sink portion SP may be recessed from the one surface 110a of the base substrate 100, and may have a stepped portion. For example, the sink portion SP may include a first recess sink portion 141 and a second recess sink portion 142 which is connected to the first recess sink portion 141. A bottom surface 141a of the first recess sink portion 141 may have a different level (for example, a higher level) from a bottom surface 142a of the second recess sink portion 142. The bottom surfaces 141 and 142a of the recesses 141 and 142 may have lower levels than the one surface 110a of the base substrate 110.

Referring again to FIG. 1A, a mapping portion 130 may be provided adjacent to the first side 111 on the one surface 110a of the base substrate 100. For example, the mapping portion 130 may be disposed between the unit regions UR of the first rows and the first side 111. The mapping portion 130 may have a function of indicating whether the unit regions UR have a defect or not. On the other hand, the mapping portion 130 may be omitted.

Referring to FIGS. 2A and 2B, semiconductor chips 200 may be mounted on the one surface 110a of the base substrate 110. The semiconductor chips 200 may be provided on the chip regions UR1, respectably. An array of the semiconductor chips 200 may correspond to the array of the unit regions UR which has been previously described in FIG. 1A. For example, the semiconductor chips 200 may be arranged along the rows C1 to C4 and columns. The semiconductor chips 200 may be electrically connected to pads 120 through connection portions 220. The connection portions 220 have a shape of a solder ball or a bump, and may include a conductive material. The semiconductor chips 200 may be mounted in various ways. For example, the semiconductor chips 200 may be electrically connected to the pads 120 by using a bonding wire (not shown).

Referring to FIGS. 3A and 3B, a molding layer 300 may be formed on the one surface 110a of the base substrate 110 to cover the semiconductor chips 200. For example, the base substrate 110 may be provided inside a mold 500 as shown in FIG. 3B. The first side 111 of the base substrate 110 may face a gate portion 510 of the mold 500. A molding compound may be supplied from the gate portion 510 of the mold 500. The molding compound may be an epoxy molding compound (EMC). The molding compound may flow on the one surface 110a of the base substrate 110 along the second direction D2. For example, the molding compound may flow sequentially from the unit regions UR of the first row C1 to the unit regions UR of the last row C4. The molding layer 300 may be formed as the molding compound covers the semiconductor chips 200. For another example, the molding layer 300 may expose upper surfaces of the semiconductor chips 200 while covering sides of the semiconductor chip 200s. The molding layer 300 may extend between the substrate 100 and the semiconductor chips 200 as the molding compound fills spaces between the connection portions 220. Accordingly, an additional process of forming an underfill film (not shown) may be omitted. It may be more difficult for the molding compound to fill the spaces between the connection portions 220 and the spaces between the substrate 100 and the semiconductor chips 200 than to cover the edge regions UR2. For example, the connection portions 220 or the semiconductor chips 200 may interrupt flow of the molding compound. Also, a material property of the molding compound may be more similar to a property of a material applied on one surface 110a of the base substrate 100 than a property of a material contained in the pads 120 and the connecting portions 220. Accordingly, the molding compound may flow more quickly in the edge regions UR2 than the chip regions UR1. However, in one row, the difference may be negligible. Therefore, in a case of rows adjacent to the first side 111, the molding layer 300 may be formed in the unit regions UR which constitute the same row substantially at the same time. The formation of the molding layer 300 may proceed in the order from the unit regions UR of the first row C1 to the unit regions UR of the last row C4. A difference between a molding rate of the chip regions UR1 and a molding rate of the edge regions UR2 in the first row C1 may be transferred to the second row C2. The more adjacent to the unit region of the last row C4, the more difference between the molding rate of the chip regions UR1 and the molding rate of the edge regions UR2 is. Hereinafter, a formation of the molding layer 300 in the last row C4 is described in more detail.

Referring to FIGS. 3B and 3C with FIG. 3A, the molding compound in the unit regions UR of the last row C4 may flow non-uniformly. Since a viscosity of the molding compound increases with time, the molding compound may flow more slowly as the molding compound flows to the second side 112. The molding compound may flow more non-uniformly in the last row C4 as the molding compound flows more slowly. At the same time in the last row C4, the molding of the edge region UR2 may be completed as in FIG. 3C, while the molding of the chip regions UR1 is in progress as in FIG. 3B. The molding compound on the edge region UR2 of the last row C4 may be disposed more adjacent to the second side 112 of the base substrate 110 than that on the chip region UR1. The molding compound remaining after molding the edge regions UR2 of the last row C4 may flow to the sink portion SP. Thus, since a phenomenon in which the molding compound remaining after molding the edge region UR2 flows in the reverse direction to the direction of columns is prevented, the molding compound remaining after molding the edge region UR2 may not re-flow into the chip region UR1. At this time, the direction of the columns is parallel to the second direction D2, and the reverse direction may be parallel to the third direction D3. In a case that the sink portion SP is omitted, a void (not shown) may be formed on the molding layer 300 on the chip region UR1 by the re-flow. At this time, the void may have a diameter of 100 μm or more. When the void has a diameter of 100 μm or more, the reliability of the semiconductor package may be deteriorated. According to the present embodiment, since a void is not formed in the molding layer 300, the reliability of the semiconductor package may be improved. In particular, the formation of a void having a diameter of 100 μm or more in the molding layer 300 may be prevented.

The rows C1 to C4 in the present embodiment may extend in the first direction D1. Accordingly, a number of columns may be more than a number of the rows C1 to C4. Further, the unit regions UR may be shift-arranged in the third direction D3 to be adjacent to the first side 111. Thus, the time required for the molding compound to flow from the first side 111 of the base substrate 110 to the last row C4 may be reduced. Accordingly, a problem of an increased viscosity by elapse of time is resolved, so that the molding compound in the last row C4 may flow more uniformly.

The finer pitch do the pads 120 and the connection portions 220 of the chip regions UR1 have, the more is the flow of the molding compound interrupted by the pads 120 and the connection portions 220. According to the present embodiment, the sink portion SP may be more effective for molding of the semiconductor chips 200 of which the unit regions UR have a fine pitch array. Accordingly, the reliability of the semiconductor package may be improved.

When the semiconductor chips 200 are thick, a heat dissipation characteristic of the semiconductor chips 200 may be excellent, but the flow of the molding compound in the molding process may be further interrupted by the semiconductor chips 200. According to the present embodiment, various semiconductor chips 200 may be used without any limitations in the thickness thereof by using the sink portion SP. For example, the molding layer 300 may cover the thick semiconductor chips 200 without generation of a void.

Referring to FIGS. 4A and 4B, it is possible to separate the unit regions UR by sewing the substrate 100. The unit regions UR may form semiconductor packages 1, respectively. The semiconductor packages 1 may include unit substrates 100a, semiconductor chips 200, and unit molding layer 300a. The unit substrate 100a may be parts of the base substrate (110 in FIGS. 3A to 3C) separated by the sewing. The unit molding layer 300a may be parts of the molding layer (300 in FIG. 3A to 3C) separated by the sewing of the base substrate (110 in FIGS. 3A to 3C). A heat dissipation portion (not shown) may be further provided on the semiconductor chip 200. The heat dissipation portion (not shown) may include a heat slug or a heat sink. When a void (not shown) is formed inside the molding layer 300, a crack may occur in the semiconductor packages 1 in the sewing process. Since the semiconductor packages 1 according to the present embodiment does not contain a void (not shown), the semiconductor packages 1 may have a superior mechanical strength. In addition, when a void (not shown) is formed inside the molding layer 300, the connection portions 220 may be electrically connected to each other. According to the present embodiment, in operation of the semiconductor packages 1, an electrical short-circuit between the connection portions 220 may be prevented.

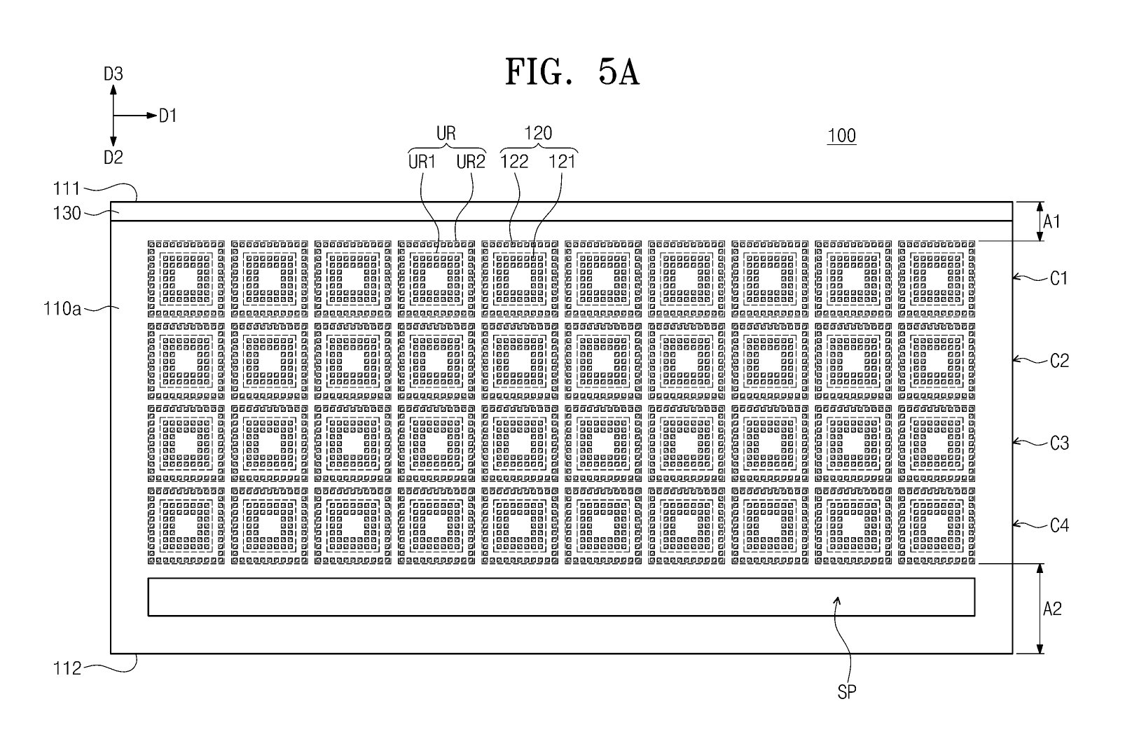

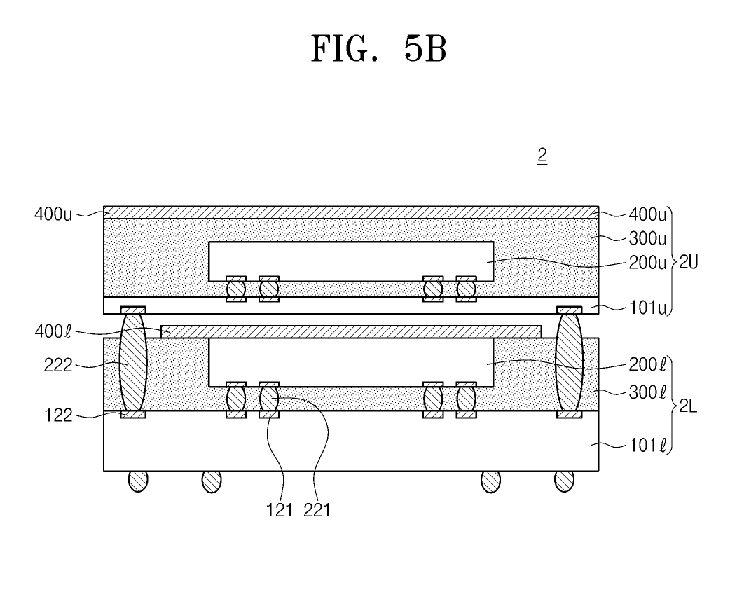

FIG. 5A is a plane view showing a package substrate according to another exemplary embodiment. FIG. 5B is a cross sectional view showing a semiconductor package fabricated by using a package substrate of FIG. 5A.

Referring to FIGS. 5A and 5B, pads 120 may be provided on the chip regions UR1 and the edge regions UR2 of the package substrate respectively. For example, first pads 121 may be provided on the chip regions UR1, and second pads 122 may be provided on in the edge regions UR2. A semiconductor package 2 of FIG. 5B may be fabricated by using the package substrate having the unit regions UR of FIG. 5A. The semiconductor package 2 may include a lower package 2L and an upper package 2U. The lower package 2L may include a lower substrate 101l, a lower semiconductor chip 200l, and a lower molding layer 300l. The lower substrate 101l, the lower semiconductor chip 200l, and the lower molding layer 300l, may be same as or similar to the unit substrate 101a of FIG. 4B, each of the semiconductor chips 200, and the unit molding layer 300a. The lower package 2L may be fabricated as described in the examples of FIGS. 1A to 4B. The lower semiconductor chip 200l may be electrically connected to the first pads 121 through connection portions 221. The second pads 122 may be exposed by removing a portion of the lower molding layer 300l. Bumps 222 may be formed on the lower substrate 101l to be connected to the second pads 122. The upper package 2U may be electrically connected to the lower the package 2L by the bumps 222. The upper package 2U may include an upper substrate 101u, an upper semiconductor chip 200u, and an upper molding layer 300u. The upper package 2U may be fabricated by the same as or similar way to that described in the examples of FIGS. 1A to 4B. The upper substrate 101u, the upper semiconductor chip 200u, and the upper molding layer 300u may be same as or similar to the unit substrate 101a of FIG. 4B, each of the semiconductor chips 200, and the molding layer 300a. A lower heat dissipation portion 400l is provided on the lower semiconductor chip 200l, and an upper heat dissipation portion 400u may be provided on the upper semiconductor chip 200u. Unlike this, at least one of the lower heat dissipation portion 400l and the upper heat dissipation portion 400u may be omitted.

Hereinafter, a mold and a forming process of a molding layer using the same according to an exemplary embodiment is described in more detail. Hereinafter, overlapped contents described above will be omitted.

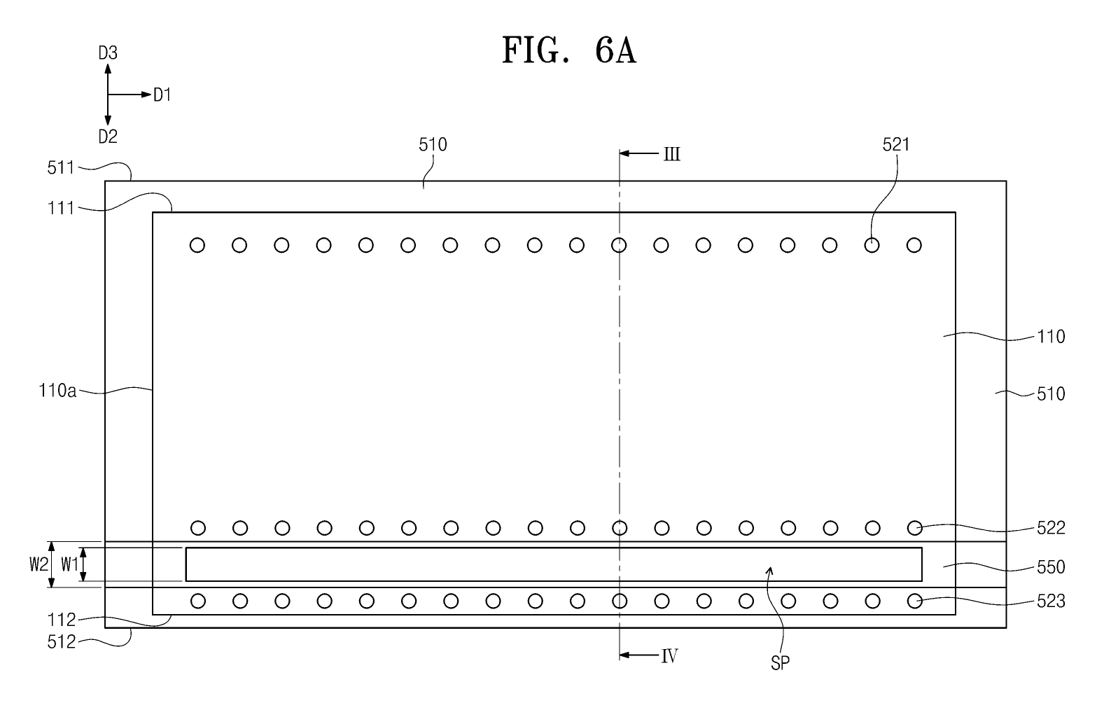

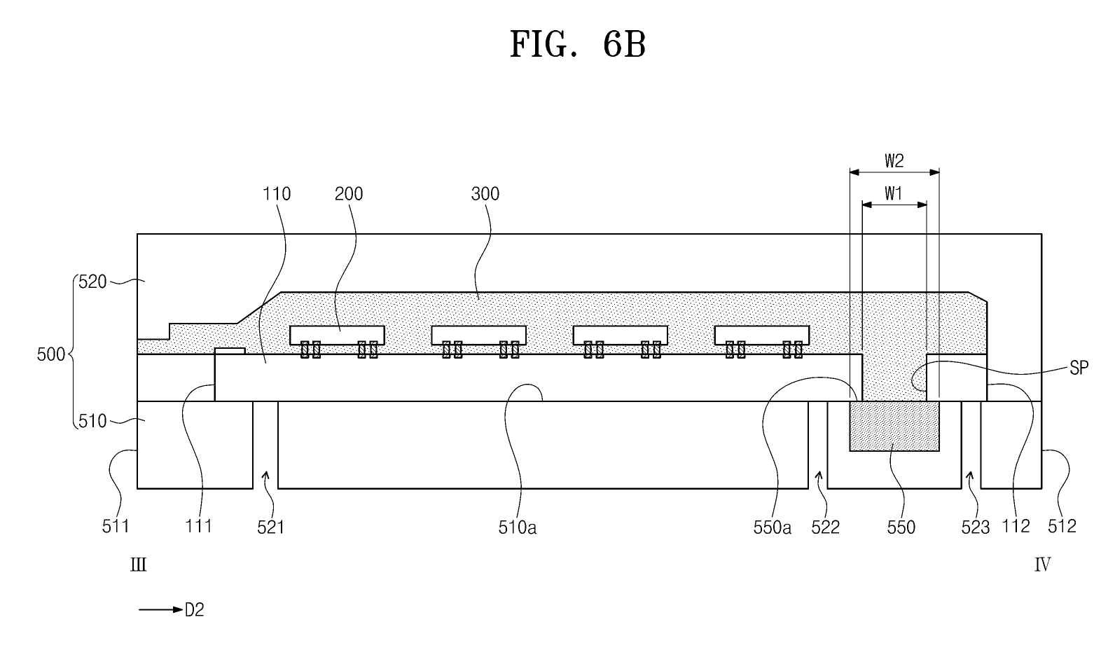

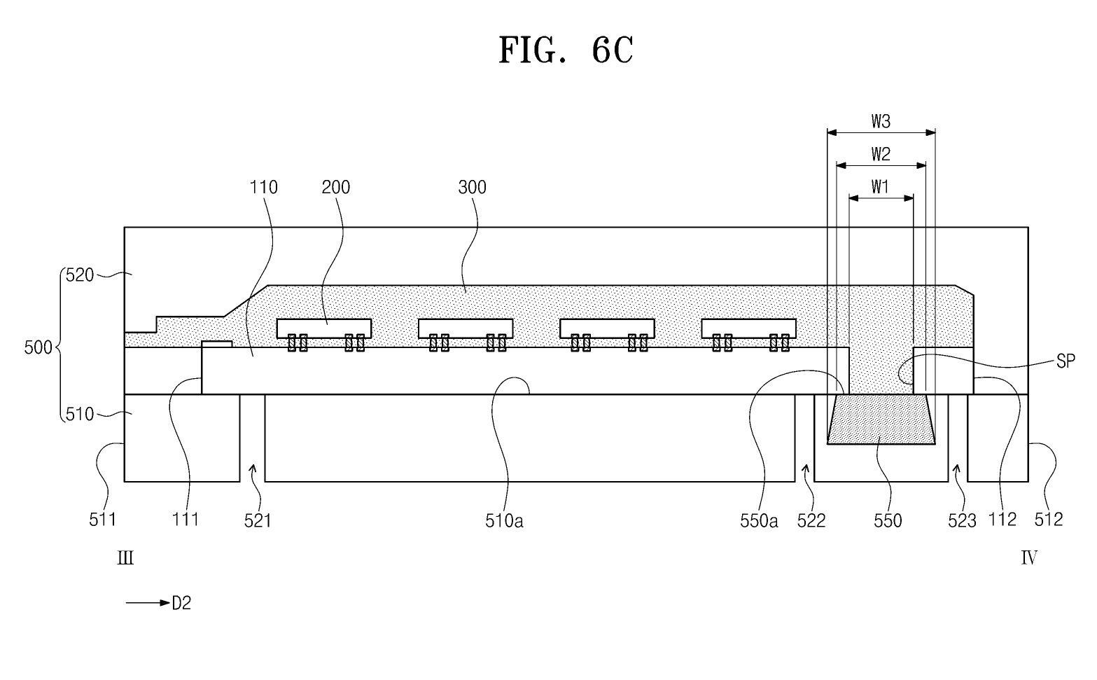

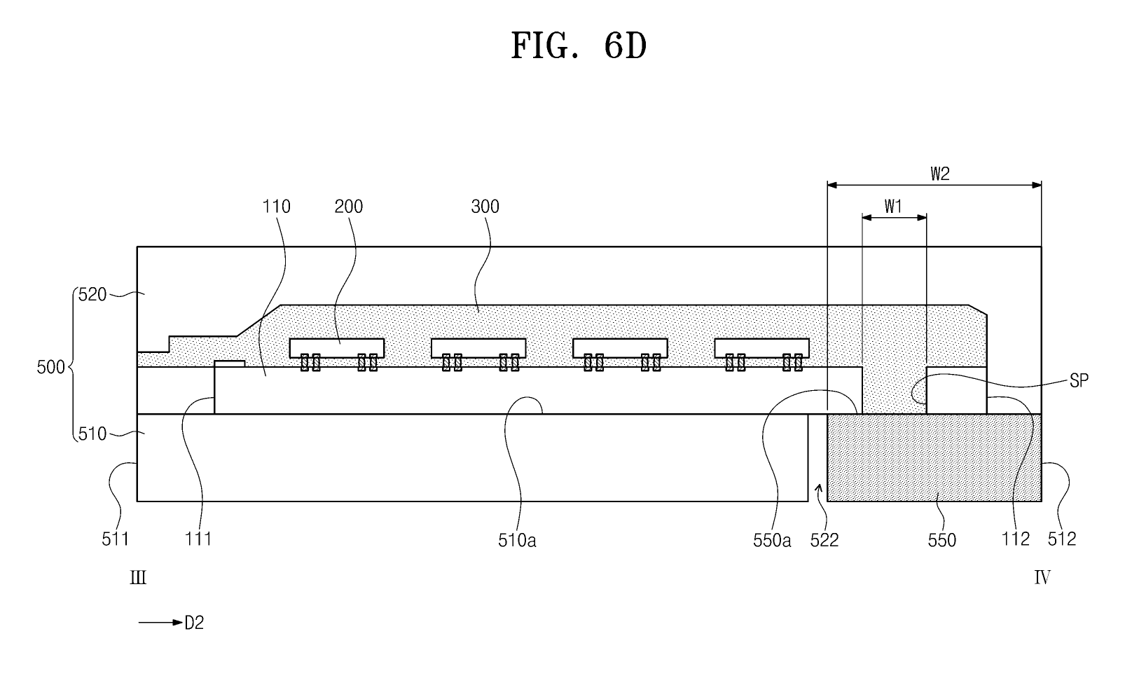

FIG. 6A is a plane view showing a mold and a formation of a molding layer using the mold according to an exemplary embodiment. FIGS. 6B to 6D are cross sectional views showing a mold and a formation of a molding layer using the mold according to an exemplary embodiment, taken along line □-□ of FIG. 6A.

Referring to FIGS. 6A and 6B, a mold 500 may include a lower frame 510 and an upper frame 520. A fixed block 550 may be provided inside the lower frame 510 of the mold 500. The fixed block 550 may be disposed adjacent to one side 512 of the lower frame 510. In a planar view, the fixed block 550 may overlap the sink portion SP, as shown in FIG. 6A. A width W2 of the upper surface 550a in the fixed block 550 may be same as or greater than a width W1 of the sink portion SP. At this time, the widths W1 and W2 may be the widths in the second direction D2. When the base substrate 110 is disposed inside the mold 500, the sink portion SP may expose an upper surface 550a of the fixed block 550. The lower frame 510 may not be exposed by the sink portion SP. The lower frame 510 includes a metal, and the fixed block 550 may include a polymer material such as Teflon. The fixed block 550 is attached preferably, but not necessarily, to the base substrate 110 than to the lower frame 510, and a gap (not shown) between the fixed block 550 and the base substrate 110 may not be formed. The upper surface 550a of the fixed block 550 may be coplanar with an upper surface 510a of the lower frame 510. Accordingly, the gap (not shown) between the fixed block 550 and the base substrate 110 may not be further formed. When the molding compound fills the sink portion SP, the molding compound may not flow into a space between the lower frame 510 and the other surface 110b of the base substrate 110. The fixed block 550 may prevent the contamination of the other surface 110b of the base substrate 110.

The lower frame 510 may have holes 521, 522, and 523 penetrating the inside thereof. These holes may be vacuum holes. The first holes 521 are adjacent to the other side 511 of the lower frame 510, and the second and the third holes 522 and 523 may be adjacent to the one side 512 of the lower frame 510. At this time, the other side 511 may be opposed to the one side 512. The second holes 522 and the third holes 523 may be disposed adjacent to the fixed block 550. The second holes 522 are provided between the first holes 521 and the fixed block 550, and the third holes 523 may be provided between the fixed block 550 and the one side 512. In a planar view, the first to third holes 521, 522, and 523 are arranged along the columns as shown in FIG. 6A, and each of arrays of the first holes 521, second holes 522, and third holds 523 may be parallel to the first direction D1. The first side 111 of the base substrate 110 may be disposed to face the first vacuum holes 521. In the forming process of molding layer 300, the base substrate 110 may be preferably, but not necessarily, fixed to the lower frame 510 by the first to third holes 521, 522, and 523. Accordingly, contamination of the other surface 110b of the base substrate 110 may be further prevented. As another example, at least one of the first to third holes 521, 522, and 523 may be omitted. As shown in FIG. 6B, the fixed block 550 may have a cross section of a rectangle.

Referring to FIG. 6C with FIG. 6A, the fixed block 550 may have a cross section of a trapezoid shape. For example, a width W2 of the upper surface 550a of the fixed block 550 may be narrower than a width W3 of the lower surface 550b of the fixed block 550. Accordingly, the fixed block 550 may be rigidly coupled to the lower frame 510. The width W2 of the upper surface 550a of the fixed block 550 may be same as or greater than a width W1 of the sink portion SP. When the base substrate 110 is disposed inside the mold 500, the sink portion SP may expose the upper surface 550a of the fixed block 550. The lower frame 510 may not be exposed by the sink portion SP. The lower frame 510 may have holes 521, 522, and 523, which may be vacuum holes, penetrating the inside thereof.

FIG. 6D is a cross sectional view showing a mold and a formation of a molding layer using the mold according to another exemplary embodiment. Hereinafter, overlapping descriptions will be omitted.

Referring to FIG. 6D with FIG. 6A, a fixed block 550 may be disposed spaced apart from a lower frame 510. An upper surface 550a of the fixed block 550 may overlap the sink portion SP of the package substrate 100. A width W2 of the upper surface 550a of the fixed block 550 may be the same as or greater than the width W1 of the sink portion SP. The upper surface 550a of the fixed block 550 may be coplanar with an upper surface 510a of the lower frame 510. The fixed block 550 may include a polymer material such as Teflon. The fixed block 550 may prevent a contamination of the other surface 110b of the base substrate 110 by the molding compound.

Hereinafter, modified examples of a sink portion of a package substrate according to an exemplary embodiment are described.

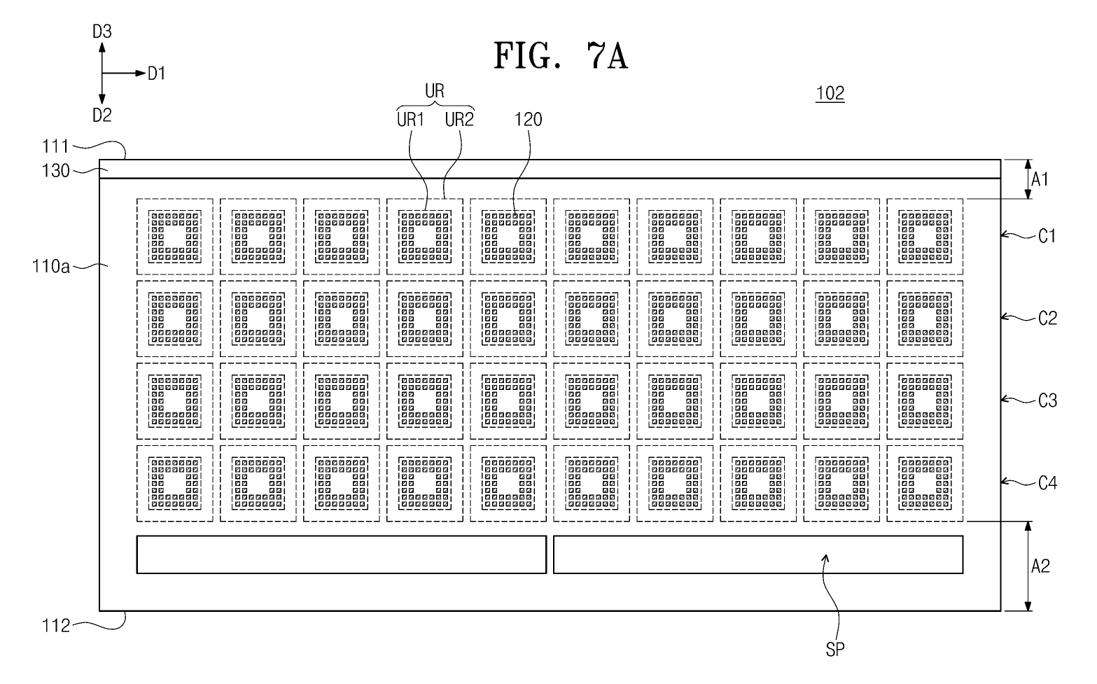

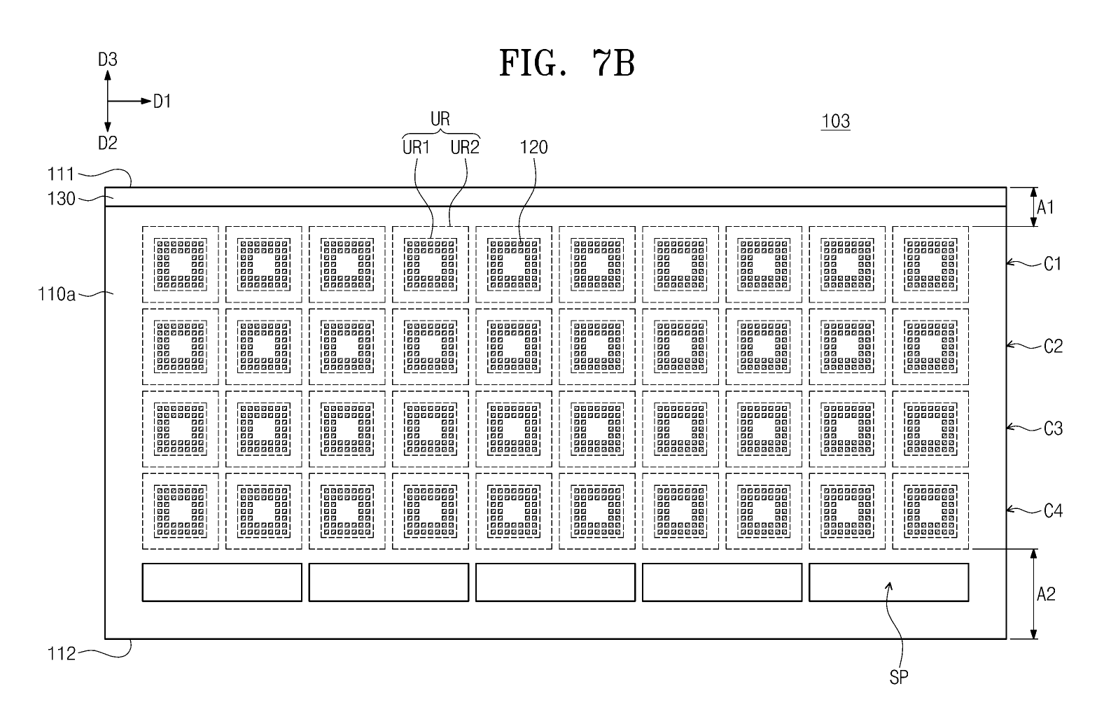

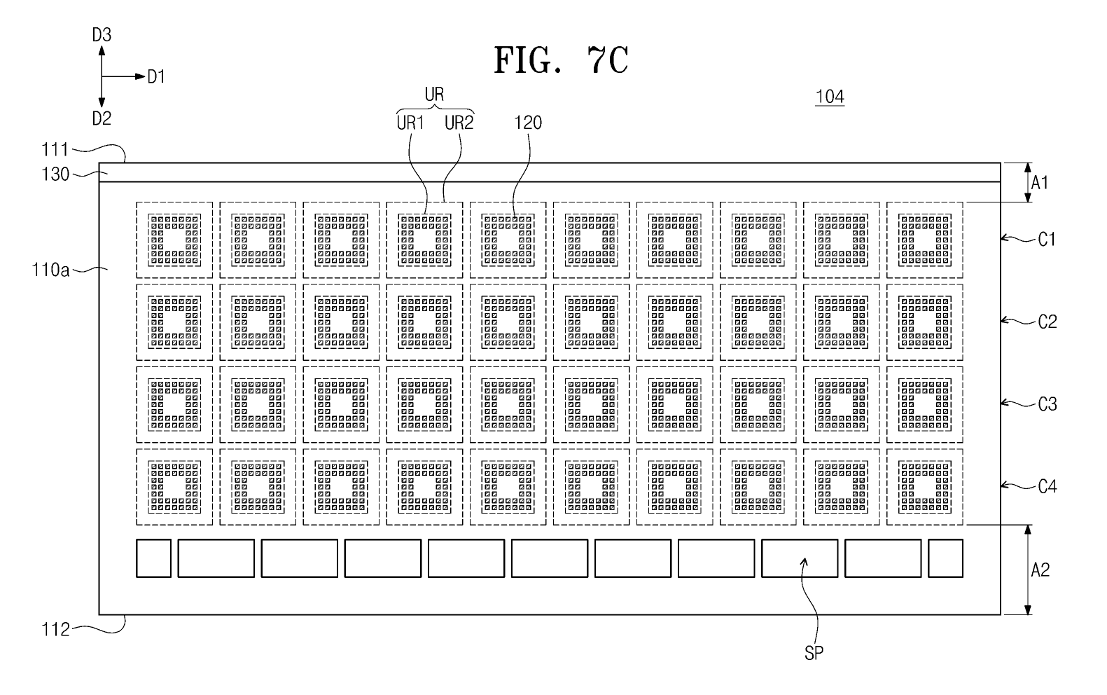

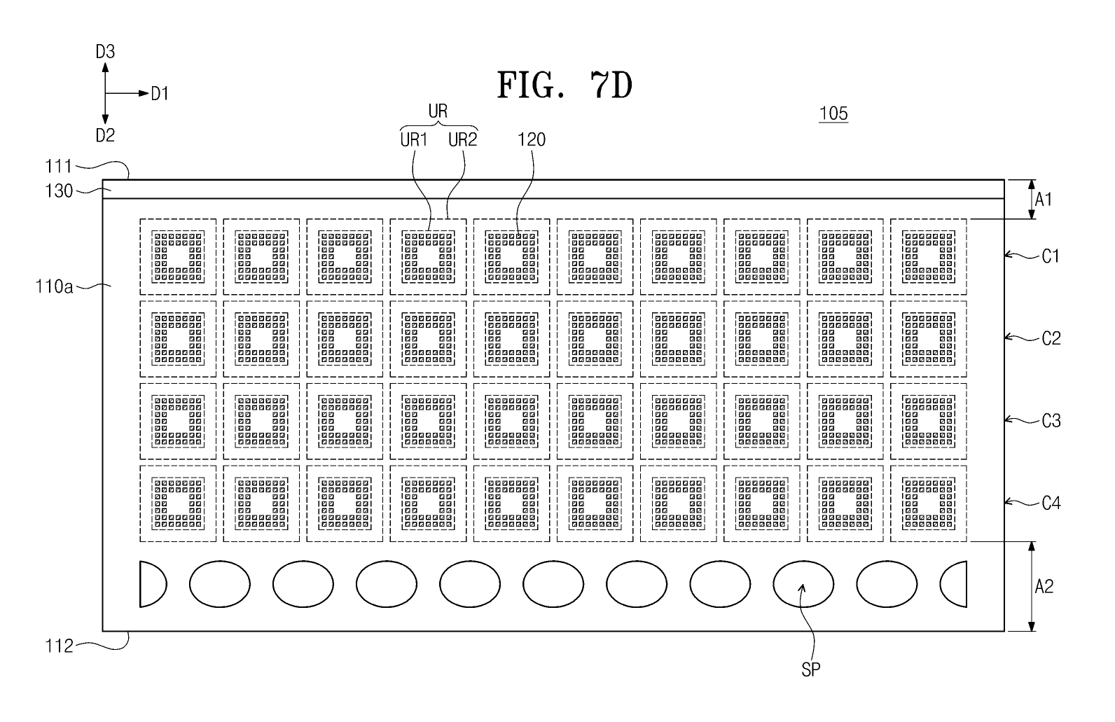

FIGS. 7A to 7D are plane views showing a package substrate according to another exemplary embodiment. Hereinafter, overlapping descriptions will be omitted.

Referring to FIGS. 7A to 7D, a sink portion SP may be provided in plurality. The sink portions SP penetrates a base substrate 110 as shown in FIG. 1B, or may be recessed from one surface 110a as shown in FIGS. 1C and 1D. The sink portions SP may be disposed adjacent to a second side 112. For example, the sink portions SP may be provided between unit regions UR of the last row C4 and the second side 112. The sink portions SP may be arranged in a first direction D1. For example, the sink portions SP may be arranged along a row. The number of the sink portions SP may vary. For example, two sink portions SP as shown in FIG. 7A, five sink portions SP as shown in FIG. 7b, eleven sink portions SP as shown in FIGS. 7C and 7D may be provided, but the inventive concept is not limited thereto.

The units regions UR may be provided on one surface 110a of the base substrate 110. The units regions UR may be arranged along a plurality of rows C1 to C4. The units regions UR may be shift-arranged in a third direction D3 to be adjacent to the first side 111.

Referring to FIG. 7C with FIG. 3A, sink portions SP may be offset-arranged in a first direction D1 with respect to chip regions UR1. For example, the sink portions SP may form columns with edge regions UR2 between the chip regions UR1 of a last row C4. Accordingly, when the molding layer 300 is formed as shown in FIG. 3A, a formation of a void (not shown) due to a non-uniform flow of the molding compound in the last row C4 may be prevented. For example, the molding compound remaining after molding the edge regions UR2 of the last row C4 may easily flow into the sink portion SP, due to the arrangement of the sink portions SP. At the same time, the molding of the edge regions UP2 of the last row C4 is completed, but the molding of the chip regions UP1 may be in process. By the sink portions SP, the molding compound remaining after molding the edge regions UP2 may not re-flow into the chip regions UR1. Each of the sink portions SP may have a cross-section of a rectangle.

Referring to FIG. 7D with FIG. 3A, sink portions SP may have a similar arrangement to those of FIG. 7C. For example, a center point of each of the sink portions SP may be offset laterally from a center point of each of the unit regions UR of the last row C4. The sink portions SP are disposed on the same lines with edge regions UR2 between chip regions UR1 of the last row C4, and the lines may extend in a second direction D2. Each of the sink portions SP may have a cross-section of a circle or an oval. However, the shape of each of the sink portions SP is not limited thereto and may vary.

The semiconductor packages according to the inventive concept may be fabricated by using any one of the package substrates 100 to 104 having the sink portions SP as described in examples of FIGS. 1A to 1C, FIG. 5A, and FIGS. 7A to 7D. The sink portions SP of the inventive concept may have a variety of shapes and sizes without being limited to the embodiments described so far.

### Embodiments

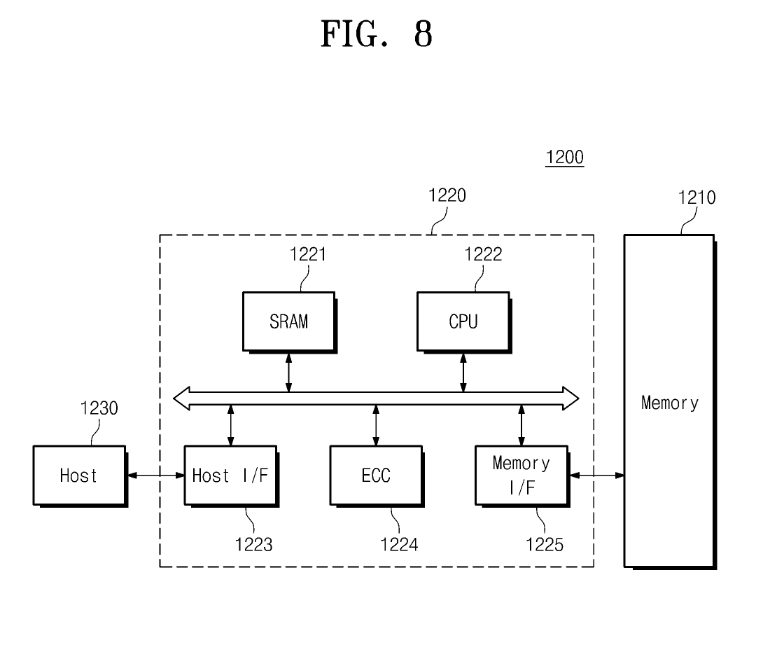

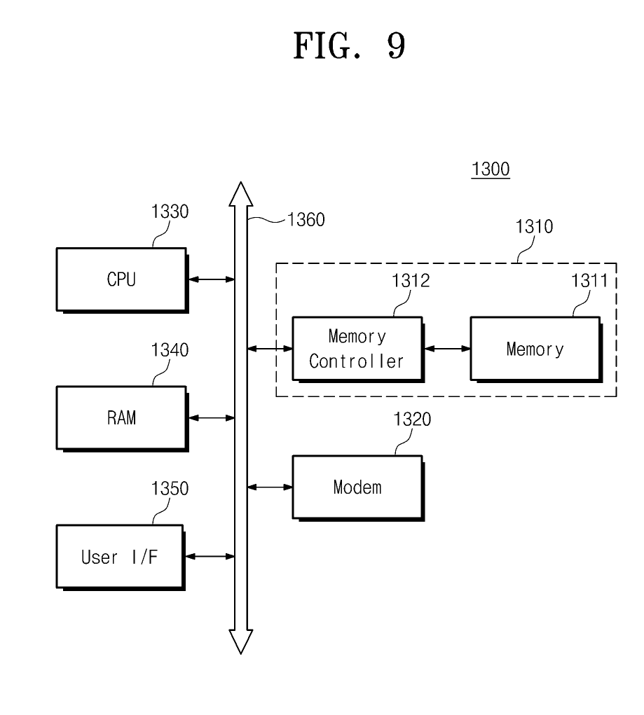

FIG. 8 is a block diagram showing a memory card provided with a semiconductor package, according to an exemplary embodiment. FIG. 9 is a block diagram showing an information processing system to which a semiconductor package is applied, according to an exemplary embodiment.

Referring to FIG. 8, a memory card 1200 may include a memory controller 1220 controlling an overall data exchange between a host and a memory 1210. A static random-access memory (SRAM) 1221 may be used as an operation memory of a central processing unit 1222. A host interface 1223 may be provided with a data exchange protocol of a host connected to the memory card 1200. An error correcting code circuit 1224 may detect and correct an error contained in the data read out from the memory 1210. A memory interface 1225 may interface with the memory 1210. The central processing unit 1222 may perform overall control operations for data exchange of the memory controller 1220. The memory 1210 may include a semiconductor package 1 of the above embodiment.

Referring to FIG. 9, an information processing system 1300 may include a memory system 1310 including the semiconductor package 1 of the above embodiment. The information processing system 1300 may include a mobile device, a computer, etc. As one example, the information processing system 1300 may include a memory system 1310, a modem 1320, a central processing unit 1330, a RAM 1340, and a user interface 1350 that are electrically connected to a system bus 1360. The memory system 1310 may include a memory 1311 and a memory controller 1312 and may be configured to be substantially the same as the memory card 1200 of FIG. 8. Data processed by the central processing unit 1330 or data input from the outside may be stored in the memory system 1310. The information processing system 1300 may be provided as a memory card, a solid state disk, a camera image sensor, and other application chipsets.

According to the above embodiments, packaging unit regions of a package substrate may be adjacent to a first side. The sink portion may be adjacent to a second side. The sink portion may be recessed form an upper surface or may penetrate a base substrate. In the packaging unit regions of a last row, a molding compound may flow non-uniformly due to a difference between a molding rate in a chip region and a molding rate in an edge region. The molding compound remaining after molding the edge regions of the last rows may flow to the sink portion. Accordingly, a phenomenon in which the molding compound remaining after molding the edge regions flows in a reverse direction of the rows may be prevented. The sink portion may prevent a formation of a void inside the molding layer. Thus, reliability of a semiconductor package according to the above embodiments may be improved.

The above embodiments are to be considered illustrative and not restrictive, and the appended claims are intended to cover all such modifications, enhancements, and other embodiments, which fall within the spirit and scope of the inventive concept. Thus, to the maximum extent allowed by law, the scope of the inventive concept is to be determined by the broadest permissible interpretation of the following claims and their equivalents, and shall not be restricted or limited by the foregoing detailed description.

What is claimed is:

1. A package substrate comprising:
a base substrate having a plurality of packaging unit regions arranged along rows and columns on one surface thereof; and
a sink portion oriented toward the other surface of the base substrate opposed to the one surface,
wherein the packaging unit regions are disposed adjacent to a first side of the one surface, the sink portion is disposed adjacent to a second side of the one surface, and the second side is opposed to the first side and is parallel to a direction of the rows.

2. The package substrate according to claim 1, wherein a distance from the packaging unit regions of a first row to the first side of the one surface is shorter than a distance from the packaging unit regions of a last row to the second side of the one surface.

3. The package substrate according to claim 1, wherein a total number of the columns is greater than a total number of the rows.

4. The package substrate according to claim 1, wherein the sink portion penetrates the base substrate and connects the one surface and the other surface.

5. The package substrate according to claim 1, wherein the sink portion is recessed from the one surface without penetrating the base substrate.

6. The package substrate according to claim 1, wherein the sink portion comprises a plurality of sink portions, and the sink portions are offset-arranged in a direction of the rows with respect to the packaging unit regions of a last row.

7. The package substrate according to claim 1, wherein each of the packaging unit regions comprises:
a chip region on which a semiconductor chip is mounted; and
an edge region surrounding the chip region.

8. The package substrate according to claim 1, wherein the sink portion is disposed spaced apart from the packaging unit regions.

9. A package substrate comprising:
a base substrate having a plurality of packaging unit regions arranged along rows and columns on one surface thereof; and
a sink portion oriented toward the other surface of the base substrate opposed to the one surface from the one surface,
wherein a shortest distance from the packaging unit regions to a first side of the one surface is shorter than a shortest distance from the packaging unit regions to a second side of the one surface, the sink portion is provided between the packaging unit regions of a last row and the second side, and the second side is opposed to the first side.

10. The package substrate according to claim 9, wherein the rows are parallel to a direction of a major axis of the one surface and the columns are parallel to a direction of a minor axis of the one surface.

11. The package substrate according to claim 9, wherein the sink portion comprises a plurality of sink portions, and the plurality of sink portions are arranged parallel to a direction of the rows.

12. The package substrate according to claim 11, wherein a center point of each of the packaging unit regions of the last row is offset in the direction of the rows from a center point of each of the sink portions.

13. The package substrate according to claim 9, wherein a total number of columns is greater than a total number of rows.

14. The semiconductor package according to claim 9, wherein a major axis of the sink portion is parallel to a direction of the rows.

15. The package substrate according to claim 9, wherein each of the packaging unit regions comprises conductive pads.

16. A semiconductor package comprising:
a base substrate comprising a plurality of packaging unit regions disposed on one side of an upper surface thereof;
a plurality of semiconductor chips disposed above the plurality of packaging units;
a sink portion oriented from the upper surface of the base substrate, and disposed on the other side of the base substrate separate from the one side of the base substrate; and
a molding layer covering the semiconductor chips and the upper surface of the base substrate,
wherein the one side of the base substrate is a side from which a molding material constituting the molding layer is flown to cover the semiconductor chips and the upper surface of the base substrate.

17. The semiconductor package of claim 16, wherein the sink portion penetrates the base substrate, and connects the upper surface and a bottom surface of the base substrate, and wherein the molding material fills in the sink portion.

18. The semiconductor package of claim 17, further comprising a mold which comprises a lower frame disposed below the bottom surface of the base substrate configured to prevent flow of the molding material beyond the base substrate.

19. The semiconductor package of claim 18, wherein a portion of the lower frame contacting the molding material comprises a polymer;

20. The semiconductor package of claim 18, the molding material comprises a material substantially similar to a material constituting the upper surface of the base substrate.
